(19) United States
(12) Patent Application Publication
(10) Pub. No.: US 2026/0304723 A1
(43) Pub. Date: Oct. 1, 2026

(54) SYSTEM AND METHOD FOR CANCELLING MAGNETIC FIELD

(71) Applicants: Tal Vitaly ZLOTNIK, Herzliya (IL); Shaul SHULMAN, Ramat Gan (IL); Oded EINAT, Herzliya (IL); SAFEFIELDS TECHNOLOGIES LTD., Herzliya (IL)

(72) Inventors: Tal Vitaly ZLOTNIK, Herzliya (IL); Shaul SHULMAN, Ramat Gan (IL); Oded EINAT

(73) Assignee: SAFEFIELDS TECHNOLOGIES LTD., Herzliya (IL)

(21) Appl. No.: 19/490,853

(22) PCT Filed: Jun. 5, 2024
(86) PCT No.: PCT/IB2024/055491

§ 371 Date: Dec. 5, 2025

(30) Foreign Application Priority Data
Jun. 8, 2023 (IL) 303572

(51) Int. Cl. H05K 9/00; B60L 50/51; G01R 15/18

(52) U.S. Cl. CPC H05K 9/0071; B60L 50/51; G01R 15/181; B60L 2240/429; B60L 2270/147

(57) ABSTRACT

A system for reducing a magnetic field in a vehicle, comprising: a passenger compartment; a three-phase electrical wiring in proximity to the passenger compartment, the three-phase electrical wiring including a first cable, a second cable, and a third cable, that when in use, generate an aggressor magnetic field in the compartment of the vehicle; a first cancellation loop having first and second legs; and a second cancellation loop having third and fourth legs, wherein the first cancellation loop includes a first non-overlapping section along at least a portion of the first cable, wherein the second cancellation loop includes a second non-overlapping section along at least a portion of the third cable, and wherein the first and second cancellation loops partially overlap along at least a portion of the second cable, to thereby facilitate cancellation of the aggressor magnetic field emanating from the three-phase electrical wiring.

### TECHNOLOGICAL FIELD

The present disclosure relates to systems and methods for cancelling, or at least reducing magnetic fields generated by current carrying elements, and relates specifically to cancelling magnetic fields generated by multiple phases of electrical current lines.

### BACKGROUND

Electromagnetic radiation, and general electromagnetic fields surrounding human environment is increasing with the use of electrical tools. Electric vehicles utilize electricity operating motors for transmitting power to the wheels and additional electrical elements that operate the vehicle.

Various other scenarios and applications may require the ability for nullifying or significantly reducing electromagnetic fields (EMF) or electromagnetic radiation in certain regions. According to medical research, low frequency magnetic radiation is believed to cause long-term adverse health effects. In some instances, such magnetic radiation may be referred to as an aggressor magnetic field. In the example of electric automobiles/vehicle, reducing the EMF radiation in the area of the passengers' seats may be desired.

WO 2023/079,550 describes a system and respective method are disclosed. The system comprising: one or more magnetic field generators configured to be positioned around a selected region, one or more magnetic field sensors configured to provide sensing data indicative of a magnetic field in said selected region, and a control system. The control system is operatively connectable to said one or more magnetic field generators and magnetic field sensors, and configured for: receiving said sensing data on the magnetic field in said selected region, processing the sensing data and determining one or more parameters of a cancellation magnetic field for cancelling or at least significantly reducing a magnitude of the magnetic field in said selected region and operating said one or more magnetic field generators for generating said cancellation magnetic field.

### GENERAL DESCRIPTION

Electric and hybrid electric vehicles utilize various electrical feed lines transmitting electrical currents between power source and respective loads. Current flowing in these electric feed lines generate magnetic fields that may vary in intensity and frequency in accordance with properties of the current. Some major current consumers in typical electric and hybrid electric vehicles are one or more electric motors that operate to convert the electrical energy to rotation energy transferred to the wheels. An electric motor or simply a motor as used herein refers to an electro-mechanical device for converting an AC signal to mechanical rotation motion, e.g., for causing one or more wheels of a vehicle to spin.

Typical electric motor used in various electric, and hybrid electric vehicles include induction motors, reluctance motors, permanent magnet synchronous motors or other electric motors. Further such electric motors typically utilize a three-phase electrical feed, including three feed wires providing alternative current with phase difference between the input wires. Electrical motors, such as induction, reluctance motors and/or permanent magnet synchronous motors are electromechanical energy conversion devices that converts electrical input (typically three-phase input electrical power) into output mechanical power. Such motors utilize a stator having a three-phase winding that is connected to an external power source and a rotor that includes at least an electrical conducting element. When the stator winding is energized, it creates a rotating magnetic field that generated torque on the rotor and rotates it. Electrical motors utilizing three-phase electrical input are used in a wide variety of applications, including vehicles, pumps, fans, conveyors, and machine tools.

Generally, rotation speed of the rotor is determined by the frequency of the stator current. In some examples, and specifically for induction motors, the rotation speed is further determined by a slip factor of the rotor. The slip factor relates to the difference between the speed of the rotating magnetic field and the speed of the rotor due to torque transmitted to the wheels. A typical slip factor may be between 2% and 5%.

The electric motors are typically the highest power consuming loads in electric or hybrid electric vehicles, requiring relatively high current input. This fact, combined with high frequency electrical current required to promote selected rotation speed leads to generation of AC magnetic fields that may leak into passenger compartment of the vehicle. A passenger compartment of a vehicle refers to a region and/or space (e.g., a cabin) enclosed within a vehicle for accommodating one or more passengers.

Thus, according to a broad aspect, the present disclosure provides a system for reducing magnetic field generated by a three-phase electric wiring, the system comprising:
at least one current source unit configured to provide at least two output currents having selected current level and frequency;
a control unit adapted for receiving data on current passing through said three-phase electric wiring and for operating said at least one current source unit to generate cancellation current for reducing magnetic field generated by the three-phase electric wiring; and
an electric wire arrangement consisting of first and second electric wire loops, wherein the first wire loop is aligned to conform with electric cable of a first phase wiring in one direction and with electric cable of third phase wiring in a return direction, and wherein the second wire loop is aligned to conform with electric cable of a second phase wiring in one direction and with electric cable of the third phase wiring in a return direction.

According to some embodiments, the system may comprise at least one sensor configured to provide sensing data indicating of current passing through said three-phase electric wiring.

According to some embodiments, the at least one sensor comprises a current sensor positioned for sensing data on current transmitted through at least one of said three-phase electric wiring.

According to some embodiments, the control unit is connectable to an external control for receiving input data indicative of current transmitted through said three-phase electric wiring. According to some embodiments, the external control is a vehicle management computer.

According to some embodiments, the at least one current source unit is configured to transmit alternating current having phase shift of ±120 degrees between said first and second electric wire loops.

According to some embodiments, the at least one current source is configured to generate electric current having amplitude similar to current amplitude in said three-phase electric wiring.

According to some embodiments, the current amplitude is varied by a current gain factor for compensating on misalignment between said three-phase electric wiring and said first and second electric wire loops. In this connection the term misalignment is to be understood broadly. More specifically, in some configurations access to the three-phase electric feed may be limited. This may be solved by placing the first and second wire loops at a selected distance from the electric feed, where spatial shape of the first and second wire loops conform to arrangement of the respective cables of the electric feed. In some other configurations, alignment between the cables of the three-phase electric feed and the first and second wire loops may be imperfect, leading to reduction of the magnetic field, while leaving certain residual magnetic field that is not canceled.

According to some embodiments, the first and second electric wire loops being configured with two or more windings, confirming with respective path of electric cables of said three-phase electric wiring, thereby generating selected cancellation magnetic field utilizing reduced electrical current input.

According to one other broad aspect, the present disclosure provides a method for reducing magnetic fields generated by a three-phase electrical feed line, the method comprising: aligning two electrical wires to conform with two of the three-phase feed lines extending from a power source to a load, and aligning said two electrical wires in a reverse direction to conform with a third of the three-phase feed lines from the load to the power source; detecting data on current passed through the three-phase electrical feed line and transmitting an opposite current pattern through the two electrical wires, thereby cancelling magnetic field generated by said three-phase electrical feed line.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 illustrates a three-phase electrical feed lines;

FIG. 2 exemplifies an arrangement of magnetic field cancellation wires according to some embodiments of the present disclosure;

FIG. 3 exemplifies a control system for magnetic field cancellation system according to some embodiments of the present disclosure; and

FIG. 4 exemplifies an arrangement of magnetic field cancellation wires using two or more windings according to some embodiments of the present disclosure.

FIGS. 5A and 5B exemplify a system utilizing electrical elements and including one or more current carrying loops, FIG. 5A illustrates the system and FIG. 5B illustrates the system with magnetic field cancellation system according to some embodiments of the present disclosure;

FIG. 6 exemplifies configuration of magnetic field cancellation system according to some embodiments of the present disclosure;

FIG. 7 exemplifies magnetic field cancellation system configuration set for optimizing output current according to some embodiments of the present disclosure;

FIG. 8 is a flow chart diagram exemplifying technique for cancelling magnetic fields according to some embodiments of the present disclosure; and

FIGS. 9A to 9D show experimentally measured magnetic field in a vehicle with a system according to the present disclosure turned off and on, FIG. 9A shows measurement sin a parking vehicle, FIG. 9B shows measurements in slow speed driving, FIG. 9C shows measurements in city environment with a system according to the present disclosure turned off and on, and FIG. 9D shows measurement during drive intercity road with a system according to the present disclosure turned off and on.

FIG. 10 shows an exemplary cancellation system installed in a vehicle, consistent with some embodiments of the present disclosure.

### DETAILED DESCRIPTION OF EMBODIMENTS

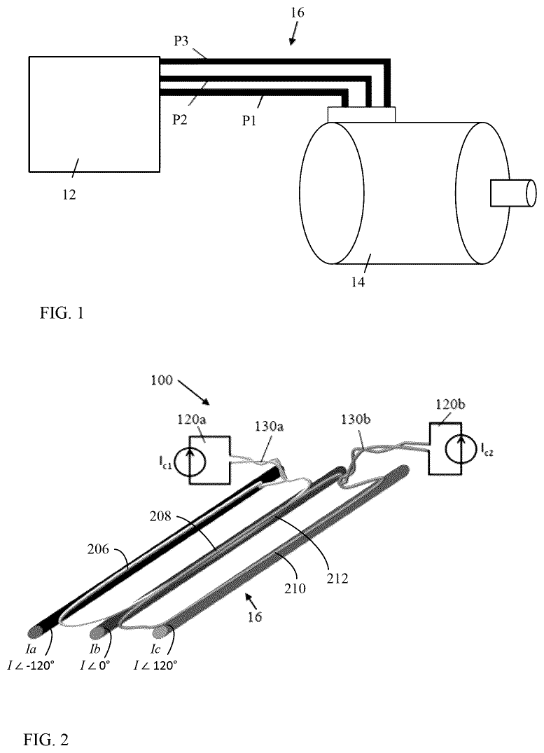

As indicated above, the present disclosure provides system, and method for active cancellation of magnetic field, and specifically for cancellation of magnetic field generated by a three-phase electrical system (e.g., an aggressor magnetic field). The terms “wire” and “cable” are used interchangeably herein and may refer to an elongated electrical conductor (e.g., a filament or a group of filaments) for conveying an electrical current from one location to another location. A wire and/or cable may be made of conductive material, such as copper, gold, aluminum, silver, platinum, brass, steel, bronze, graphite, and/or any other conductive material capable of taking on an elongated shape. A filament in this context refers to a strand or elongated structure significantly longer than wide. In this connection reference is made to FIG. 1 illustrating schematically a load 14 such as an electrical motor is connected to a power source 12, e.g., an inverter unit, using three-phase electrical wiring 16 including first P1, second P2 and third P3 phase cables.

In some disclosed embodiments, the three-phase electrical wiring connects an inverter to a motor. An inverter refers to an electronic device for converting a DC signal to an AC signal. Thus, power source 12 (e.g. which could be an inverter unit) may include a DC power source (e.g., a battery) connected to an inverter (e.g., a DC-AC converter) for converting a DC output of the DC power source to an AC signal. In some embodiments, an inverter may be a three-phase inverter for converting a DC signal to a three-phase AC signal. A three-phase electrical wiring may deliver the three-phase AC signal from the inverter to the motor for powering the vehicle.

A phase may refer to a specific point in the cycle of a waveform, and may be expressed as an angle in degrees (°), and/or in radians (rad). A phase may describe a position of a waveform relative to a reference point in time and/or relative to another waveform. The phase angle of a waveform may indicate a position within a cycle of the waveform at a given point in time. Phase shifted refers to a phase difference between two or more signals and may correspond to an amount of time by which one waveform leads or lags behind another waveform. A three-phase electrical wiring refers to three wires (e.g., bundled as a cable), each wire dedicated to carrying an AC signal phase shifted from AC signals flowing in the other two wires. Thus, a three-phase wiring may carry three AC signals, each AC signal shifted in phase from the other two AC signals. The three-phase electrical wiring generally carries electrical power having ±120° spaced apart currents Iₐ, I_{b} and I_{c} in a three-phase configuration. The term wire, as used herein, refers to one or more elongated strands, rods, or other conductors for conveying electricity and/or signals. Wires may be completely flexible along their entire length, partially flexible along some portions of their length, or completely inflexible, depending on implementation.

In some disclosed embodiments, when in use, AC current flowing through the first, second, and third cables are phase shifted from each other by 120°. When in use refers to time period during which AC current flows through some or all portions of the three-phase electrical wiring. Such flow may occur, for example, to power one or more vehicle components, e.g., when a motor of a vehicle is operating to turn one or more wheels or when another electrical component is in use. During this time period, an aggressor magnetic field produced by current flowing through one or more of the wires may radiate into the passenger compartment of the vehicle. By way of a non-limiting example, in FIG. 2, when in use, AC current flowing through first cable Ia, second cable Ib, and third cable Ic of three-phase electrical wiring 16 may be phase shifted from each other by 120°.

Without loss of generality, electric current passing through the cables can be described by:

$${I}_{a} = {I}_{0} cos ( 2 π ft - 120 ° )$$

$${I}_{b} = {I}_{0} cos ( 2 π ft )$$

$${I}_{c} = {I}_{0} cos ( 2 π ft + 120 ° )$$

Where f is the frequency of the current and I₀ is its amplitude. It should be noted that the three-phase electrical power may vary in time and may be in the form of any time varying function showing phase shifts between the three-phase cables. The current may be processed as a sum of sine or cosine functions (e.g., Fourier sum) and frequency of the alternative current may change in time as is used in various electrical motors.

When in use, transmission of current through the electric wiring and operation of the electric motor may generate a non-zero aggressor magnetic field, which varies in time in accordance with the current frequency. The aggressor magnetic field may propagate in space. For example, in an electric vehicle, the aggressor magnetic field may propagate into the passenger compartment and affect passengers of the vehicle. The present disclosure provides systems, computer readable medium, and methods for eliminating, or at least reducing magnetic fields in a vehicle generated by three-phase electrical current and/or operation of a three-phase electrical motor. Reducing a magnetic field refers to lessening, decreasing, and/or diminishing a magnetic field (e.g., below a threshold value).

Reference is made to FIG. 2 exemplifying general configuration of a magnetic field cancelling system 100 according to some embodiments of the present disclosure. The system includes a current source arrangement 120, including in this example a first current source 120a and a second current source 120b, and respective electric wire arrangement 130. The electric wire arrangement includes first and second electric wire loops (e.g., cancellation loops), 130a and 130b connected respectively to the first and second current sources 120a and 120b.

A wire loop (e.g., a cancellation loop) may include an elongated filament having a closed geometrical shape. A wire loop may have a round shape (e.g., circular and/or oval), a polygon shape (e.g., a square, a rectangle, a triangle, and/or any other polygon), and/or any other closed geometrical shape. A wire loop may be included in an electrical circuit to provide a path for current to travel from a current source through elements of the circuit, and back to the source. A wire loop may not be uniform in structure. For example, only a portion of a wire loop may be formed of wire, and the remainder may be formed of other materials or components such as a portion of a vehicle frame (e.g., part of a vehicle chassis) or other electrically conductive structure. t least a portion of a wire loop (e.g., a cancellation loop) in proximity to a first magnetic field may permit generation of a second magnetic field for cancelling the first magnetic field.

To cancel or at least reduce magnetic field generated by current transmitted in three-phase electrical wiring 16, the first and second electric wire cancellation loops 130a and 130b are placed to conform with the three-phase electrical wiring 16. In some disclosed embodiments, three-phase electrical wiring 16 may be in proximity to a passenger compartment of a vehicle. A three-phase electrical wiring in proximity to a passenger compartment refers to a three-phase electrical wiring positioned sufficiently close to the passenger compartment such that a magnetic field generated by the three-phase electric wiring radiates into the passenger compartment. For example, a three-phase wiring feeding a three-phase signal from an AC power source to a motor of an electric and/or hybrid vehicle may be in proximity to the passenger compartment. At least a portion of a three-phase cable may be located, for example, along a vehicle chassis (e.g., beneath a passenger compartment), in a rear, front, top, bottom, side of a vehicle, beneath and/or alongside a passenger seat, beneath a passenger compartment floor, and/or in any other region of the vehicle. Some disclosed embodiments may involve a three-phase electrical wiring including a first cable, a second cable, and a third cable, that when in use, generate an aggressor magnetic field in the passenger compartment of the vehicle. Thus, each of the first cable, second cable, and third cable may be dedicated to carrying an AC signal that is shifted in phase from AC signals carried by the other two cables of the three-phase electrical wiring. When the vehicle is in operation (e.g., in use), three phase-shifted AC signals flowing through each of the first, second, and third cables may generate an aggressor magnetic field that may radiate into the passenger compartment of the vehicle.

By way of a non-limiting example, in FIG. 2, three-phase electrical wiring 16 may be located in a vehicle, e.g., for delivering an AC signal from an AC power source to a motor. Three-phase electrical wiring 16 may include a first cable Iₐ, a second cable I_{b}, and a third cable I_{c}, that when in use, generate an aggressor magnetic field in the compartment of the vehicle.

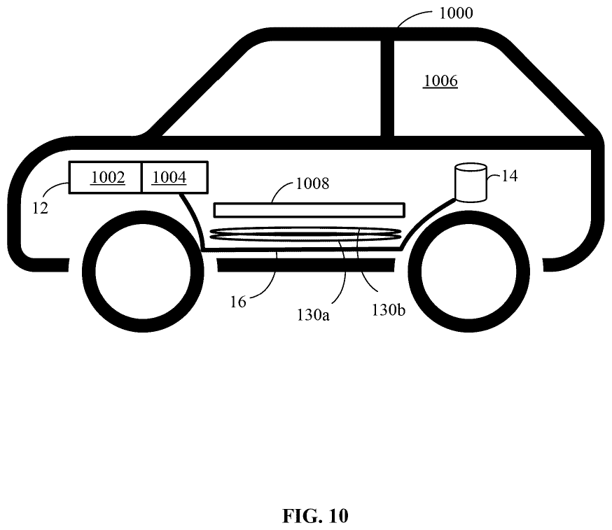

By way of another non-limiting example, reference is made to FIG. 10 which illustrates an exemplary cancellation system installed in a vehicle 1000, consistent with embodiments of the present disclosure. Vehicle 1000 may include power source 12. Power source 12 may include a battery 1002 (e.g., a DC power source) connected an inverter 1004 (e.g., a DC-AC converter) for converting DC energy to an AC power signal. Three-phase electrical wiring 16 may be located in vehicle 1000 for delivering an AC signal from power source 12 to load 14 (e.g., a motor).

More specifically, in FIG. 2, a first electric wire cancellation loop 130a is aligned with a first electric cable Iₐ of three-phase wiring 16 in one direction, and is aligned with a second cable I_{b} of three-phase wiring 16 in its return path. Similarly, the second electric wire cancellation loop 130b is aligned with a third electric cable I_{c} of three-phase wiring 16 in one direction and aligned with the second cable I_{b} of three-phase wiring 16 in its return path. Accordingly, first electric wire cancellation loop 130a is aligned with first electric cable Iₐ of three-phase wiring 16 and oppositely aligned with second cable I_{b} of three-phase wiring 16, and second electric wire cancellation loop 130b is aligned with third cable I_{c} of three-phase wiring 16 and oppositely aligned with second cable I_{b} of three-phase wiring 16.

In some disclosed embodiments, first cancellation loop may have a first leg and a second leg, and second cancellation loop may have a third leg and a fourth leg A leg of a cancellation loop may include a portion of the cancellation loop. In some embodiments, a leg of a cancellation loop may include a substantially straight portion of the cancellation loop. For example, a leg of a cancellation loop may include a portion of a cancellation loop permitting current to flow in a first direction (e.g., along a substantially straight line), prior to a reaching a non-straight portion of the cancellation that may cause the current to revert back in a second direction opposite the first direction. Thus, the first leg of the first cancellation loop may be a first substantially straight portion of the first cancellation loop permitting current to flow in one direction, and the second leg of the first cancellation loop may be a second substantially straight portion of the first cancellation loop permitting current to flow in the opposite direction (e.g., as a return path to the path provided by the first leg). Similarly, the third leg of the second cancellation loop may be a first substantially straight portion of the second cancellation loop permitting current to flow in one direction, and the fourth leg of the second cancellation loop may be a second substantially straight portion of the second cancellation loop permitting current to flow in the opposite direction (e.g., as a return path to the path provided by the third leg). Legs need not be linear. They can curve or meander with adjacent wires causing field cancelling as they meander adjacent each other.

By way of a non-limiting example, in FIG. 2, first cancellation loop 130a may have a first leg 206 and a second leg 208, and second cancellation loop 130b may have a third leg 210 and a fourth leg 212

In some disclosed embodiments, the first cancellation loop may include a first non-overlapping section along at least a portion of first cable. For example, at least a portion of the first leg of the first cancellation loop may be located alongside, adjacent to, and/or flush with a portion of the first cable of the three-phase electric wiring. In some disclosed embodiments, the second cancellation loop may include a second non-overlapping section along at least a portion of the third cable. For example, at least a portion of the third leg of the second cancellation loop may be located alongside, adjacent to, and/or flush with a portion of the third cable. A non-overlapping section of a cancellation loop refers to a portion of a cancellation loop lacking a shared and/or common space or overlap with a portion of another cancellation loop. For example, two cancellation loops may be arranged to partially overlap, such that portions of the two cancellation loops may occupy and/or share the same space and/or region (e.g., two legs of two different cancellation loops may run alongside each other, and thereby at least partially overlap). Portions of any of the two cancellation loops external to the shared space and/or region may be non-overlapping sections. Along a portion of a cable refers to abutting, adjacent to, and/or flanking. For example, positioning a section of a cancellation loop along a portion of a cable may permit a magnetic field generated by an AC signal flowing in the section of the cancellation loop to at least partially cancel a magnetic field generated by another AC signal flowing in the portion of the cable.

By way of a non-limiting example, in FIG. 2, first cancellation loop 130a may include a first non-overlapping section along at least a portion of first cable Ia. Second cancellation loop 130b may include a second non-overlapping section along at least a portion of third cable Ic. For example, at least a portion of first leg 206 of first cancellation loop 130a may be located alongside flush with a portion of first cable Ia, and at least a portion of third leg 210 of second cancellation loop 130b may be located flush with a portion of third cable Ic.

In some disclosed embodiments, the first cancellation loop and the second cancellation loop may partially overlap along at least a portion of the second cable, to thereby facilitate cancellation of the aggressor magnetic field emanating from the three-phase electrical wiring. To partially overlap refers to at least a section of the first cancellation loop and at least a section of the second cancellation loop sharing and/or lying adjacent each other. For example, sections of the first and second cancellation loops may abut and/or align flush and/or adjacent to each other. In some embodiments, an external coating of a section of the first cancellation loop may touch an external coating of a section of the second cancellation loop in the partially overlapping region. To facilitate refers to enable, permit, and/or advance. Emanating refers to emitting, radiating, and/or projecting. Cancellation of an aggressor magnetic field refers to annulling, neutralizing, offsetting, and/or counteracting an aggressor magnetic field.

By way of a non-limiting example, in FIG. 2, first cancellation loop 130a and second cancellation loop 130b may partially overlap along at least a portion of second cable Ib, to thereby facilitate cancellation of the aggressor magnetic field emanating from three-phase electrical wiring 16.

In some disclosed embodiments, the system may be configured such that when in use, currents flow in opposing directions in the partially overlapping portion. Opposing directions refers to contrary and/or opposite trajectories and/or orientations. By way of a non-limiting example, in FIG. 2, in the region along second cable Ib where second leg 208 of first cancellation loop 130a overlaps with fourth leg 212 of second cancellation loop 130b, current flowing through second leg 208 may flow in a direction contrary to current flowing through fourth leg 212 of second cancellation loop 130b.

In some disclosed embodiments, current flowing in the non-overlapping section of the first cancellation loop along the at least portion of the first cable substantially cancels current flowing in the at least portion of the first cable. An (e.g., first) current cancelling an (e.g., second) current refers to providing the first current substantially equal in magnitude but opposite in direction to the second current, thereby substantially neutralizing and/or annulling the second current. Cancelling the second current may cause a corresponding cancellation of a magnetic field generated by the second current. mitigate propagation of a magnetic field. By way of a non-limiting example, in FIG. 2, current flowing in the non-overlapping section (e.g., at least a portion of first leg 206) of first cancellation loop 130a along the at least portion of first cable Ia may substantially cancel current flowing in the at least portion of first cable Ia. Cancelling the current thus may cause cancellation of a magnetic field generated by the current flowing along the portion of first cable Ia.

In some disclosed embodiments, current flowing in the non-overlapping section of the second cancellation loop along the at least portion of the third cable substantially cancels current flowing in the at least portion of the third cable. By way of a non-limiting example, in FIG. 2, current flowing in the non-overlapping section (e.g., at least a portion of third leg 210) of second cancellation loop 130b along the at least portion of third cable Ic may substantially cancel current flowing in the at least portion of the third cable Ic. Cancelling the current thus may cause cancellation of a magnetic field generated by the current flowing along the portion of first cable Ic.

In some disclosed embodiments, a combined current flowing in the partial overlap of the first cancellation loop and the second cancellation loop substantially cancels current flowing in the second cable. A combined current refers to an aggregate current produced by summing two or more currents (e.g., a net current flow). Although the currents may physically flow independent of each other in each wire, a magnetic field radiating from the adjacent wires may correspond to a magnetic field produced by the combined current. A combined current flowing in the partial overlap of the first cancellation loop and the second cancellation loop refers to an (e.g., mathematical) summation of the current flowing in second leg of the first cancellation loop and the current flowing in the fourth leg of the second cancellation loop in the region with the second leg and fourth leg overlap in alignment with the second cable of the three-phase electrical wiring. The combination of the currents flowing in the second leg of the first cancellation loop and the fourth leg of the second cancellation loop may substantially offset and/or counter current flowing through the second cable of the three-phase electrical wiring. Producing a cancelation current substantially equal in magnitude but opposite in direction to a current flowing in the second cable may cause cancellation of a magnetic field generated by the current flowing along the portion of the second cable.

By way of a non-limiting example, in FIG. 2, current flowing in second leg 208 of first cancellation loop 130a partially overlapping with second cancellation loop 130b, may be combined with current flowing in fourth leg 212 of second cancellation loop 130b at the overlapping region. The combined current flowing in the partial overlap of first cancellation loop 130a and the second cancellation loop 130b may substantially cancel current flowing in second cable Ib.

Some disclosed embodiments include ferromagnetic shielding material between a three-phase electrical wiring and a passenger compartment for attenuating an aggressor magnetic field generated by the three-phase electrical wiring. Ferromagnetic shielding material refers to a material used to block or reduce an influence of a magnetic field. Ferromagnetic shield materials may have high magnetic permeability, which allows to attract and channel magnetic field lines, thereby protecting the shielded area from magnetic interference. Some examples of ferromagnetic shielding material may include ferromagnetic metal, such as steel, iron, nickel, and/or cobalt. Attenuating refers to weakening, lessening, and/or diminishing.

By way of a non-limiting example, in FIG. 10, three-phase electrical wiring 16 may connect inverter 1004 to load 14 (e.g., a motor), thereby generating an aggressor magnetic field which may radiate into a passenger compartment 1006 of vehicle 1000. First cancellation loop 130a and second cancellation loop 130b may be located to at least partially cancel the aggressor magnetic field generated by three-phase electrical wiring 16. For example, first cancellation loop 130a and second cancellation loop 130b may be located between three-phase electrical wiring 16 and passenger compartment 1006, to thereby at least partially block the aggressor magnetic field generated by -phase electrical wiring 16 from radiating into passenger compartment 1006. Vehicle 1000 may additionally include ferromagnetic shielding material 1008 for preventing the aggressor magnetic field from radiating into passenger compartment 1006. For example, ferromagnetic shielding material 1000 located between three-phase electrical wiring 16 and passenger compartment 1006 may attenuate the aggressor magnetic field generated by three-phase loop electrical wiring 16.

More specifically, the magnetic field cancellation system may operate to transmit currents through the first and second wire loops in accordance with input data indicative of current flowing in the three-phase electrical wiring 16, such that a first wire loop 130a carries current of I1=−Iₐ and second wire loop 130b carries current of I2=−I_{c}. The combination of currents transmitted through both wire loops in the return path conforming with cable I_{b} is:

$$- ( I 1 + I 2 ) = {I}_{a} + {I}_{c} = {I}_{0} cos ( 2 π ft - 120 ° ) + {I}_{0} cos ( 2 π ft + 120 ° ) = 2 {I}_{0} cos ( \frac{2 π ft - 120 ° + 2 π ft + 120 °}{2} ) cos ( \frac{2 π ft - 120 ° - 2 π ft - 120 °}{2} ) = 2 {I}_{0} cos ( 2 π ft ) cos ( - 120 ° ) = - {I}_{0} cos ( 2 π ft ) = - {I}_{b}$$

Thus, the use of first and second wire loop, and suitable arrangement of the electric wires of the loops enables cancellation of all three currents in the three phase wires are canceled by the currents in the loops and if they are placed in proximity to the three phase wires, the magnetic field will be canceled.

This configuration is optimal when the first and second wire loops are aligned to conform directly on the electric three-phase feed wires. However, in some embodiments, the first and second wire loops may be placed at a selected distance from the three-phase cables. In this connection, the first and second wire loops may be placed at a selected location between the region where the three-phase cables pass and the passenger area of the vehicle, to reduce and preferably cancel magnetic field within the passenger area of the vehicle. This configuration may be used when access to location of the three-phase cables is limited, e.g., when the cables are located and/or passing through the motor packaging.

In such configurations, where the first and second wire loops are located at a distance from the three-phased cables, quality of field cancelation generally declines as this distance grows. Further, the cancellation current, transmitted through the first and second wire loops is varied by a suitable gain parameter a, so that I1=−αIₐ, I2=−αI_{b}. The gain parameter a may be determined based on variation in magnetic field amplitude at location of the first and second wire loops.

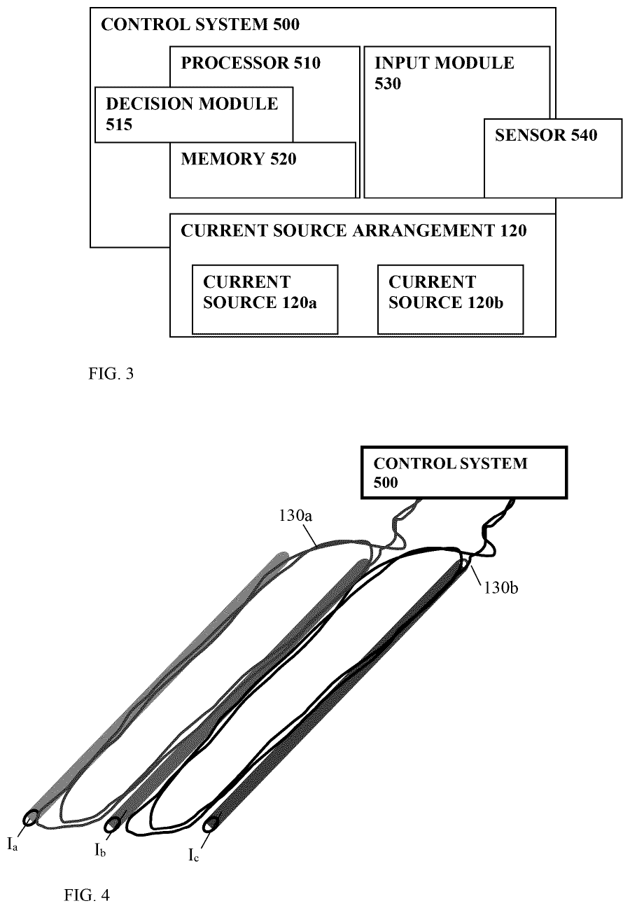

As indicated above, the first and second magnetic field cancellation loops are connected to respective current source arrangement 120 and controlled using a control system. Reference is made to FIG. 3 exemplifying a control system configuration according to some embodiments of the present disclosure. FIG. 3 illustrates a control system 500 including at least one processor 510 and memory 520 forming together a processor and memory circuitry. The control system also includes an input module 530 configured to receive input data indicative of magnetic field to be canceled, and a current source arrangement 120 configured to generate and transmit selected currents to the first and second magnetic field cancellation loops 130a and 130b.

The control system 500 is exemplified in FIG. 3 as including at least one processor 510 and memory 520. It should however be understood that the control system may utilize analog processing, and may generally utilize an electric circuit configured to receive input data on parameters of the three-phase current Iₐ, I_{b} and I_{c}, and generate cancellation current I1 and I2 as described above. Such electric circuit may utilize one or more (generally two) amplifier circuits routed to receive input signal indicating of at least one of Iₐ, I_{b} and I_{c}, and generate output current I1 and I2. Such input signal may be transmitted from one or more sensors, electrical connection to three-phase electric feed, current prob, and/or input data from a vehicle control system.

Generally, a three-phase electric feed may operate with sinusoidal alternating current profile. Further, for a typical electric motor, motor operation speed is determined by frequency of electrical currents transmitted by the three-phase electric feed. Accordingly, the control system may require input data indicative of current amplitude, frequency, and phase to determine output current for cancelling or at least reducing magnetic fields generated by the electrical three-phase feed. Thus, according to some embodiments, the input module 530 may be connected or connectable to a vehicle computer system to receive data indicative of operation mode of the vehicle's electric motor. Operation mode of the vehicle's electric motor may generally include data on current profile transmitted to the electric motor through the three-phase electric feed and is further indicative of magnetic field generated by the electric feed and the motor itself.

Accordingly, in some embodiments of the present disclosure, the control system 500 may be configured to receive input data indicative of electrical feed profile provided through the three-phase electric cables and operate to transmit a cancellation current through the first and second wire loops 130a and 130b. As indicated above, the cancellation current I1 and 12 may be sinusoidal current having similar frequency as the three-phase current, and comply with the requirement I1=−αIₐ, I2=−αI_{b}, where Iₐ and I_{b} are currents transmitted through two of the three-phase electric cables with which the wire loops 130a and 130b are aligned to conform, while and the first and second wire loop are both aligned to conform with the third of the three-phase cables in their return path providing that −(I1+I2)=−αI_{c}, where a is the gain factor as indicated above.

Further, the control system may be connected to one or more magnetic field sensors 540. The one or more magnetic field sensors 540 may provide data indicative of magnetic field at location of the wire loops 130a and 130b. Identifying magnitude of the magnetic field at location of the wire loops 130a and 130b may be used to determine gain parameter a. Accordingly, as indicated above the gain parameter a may be determined at installation stage, in accordance with relative location of the magnetic field cancellation wire loops 130a and 130b, and may be further periodically calibrated in accordance with sensing data collected by at least one magnetic field sensor 540.

Further, the control system 500 may utilize a magnetic field cancelling decision module 515. Such decision module may be implemented as software and/or hardware module as part of the processor 510 and/or as separate module of the control system 500. The decision module 515 may receive input data on current levels used for cancelling magnetic field by transmitting the current through the wire loops 130a and 130b, and optionally receive data on magnetic field from the one or more sensors 540. The decision module may process the received data to determine cancellation score based on level and frequency of the magnetic field and level of power required for cancelling thereof. The decision module may determine that under some conditions, cancellation of the magnetic field is to be partial, or avoided for selected times, or that the magnetic field is to be fully canceled, up to maximal cancellation ability that may be determined based on spatial arrangement of the elements. For example, the decision module may determine that magnetic field amplitude exceeds a current threshold, and attempt to transmit current that is sufficient to cancel magnetic field may be above current transmission ability of the system the field will not be cancelled or not fully cancelled. For example, if the magnetic field is too strong, the decision module 515 may determine that complete cancellation is impractical and may damage current source operation, and accordingly to determine a selected gain factor α to provide partial cancellation of the magnetic field, or to operate in pulses and cancel the magnetic field only at certain times.

The magnetic field cancellation system of the present disclosure is generally configured to cancel, or at least significantly reduce magnetic fields generated by three-phase electric feed. In this connection it should be noted that the three-phase electrical feed is generally used for generating rotating magnetic field within the electric motor. Such rotating magnetic field may radiate externally from the motor into a passenger region of the vehicle. Typically, the electric motor may be associated with a magnetic field shield used to prevent high magnetic fields outside of the motor unit. However, certain magnitude of magnetic field may be transmitted through the shield toward the passenger region. The first and second wire loops 130a and 130b may be arranged between location of the electric motor and passenger region to cancel, or at least reduce the rotating magnetic field from affecting passengers by reducing field amplitude.

In some disclosed embodiments, each of the first cancellation loop and the second cancellation loop include multiple windings. Multiple windings refers to a coil and/or a plurality of loops. For example, a wire may be wrapped around a core several times, resulting in several windings.

Reference is further made to FIG. 4 exemplifying an additional configuration of the first and second wire loops 130a and 130b according to some embodiments of the present disclosure. As show, to generate the desired cancellation (magnetic) field, the first and second wire loops 130a and 130b may transmit similar current as the three-phase cables while using one round of the path. Alternatively, as shown in FIG. 4, first and second wire cancellation loops 130a and 130b may be arranged with two or more windings, all generally conforming with the three-phase cables. This configuration, using a selected number of n windings allows current reduction by 1/n, and accordingly to provide power saving to the system.

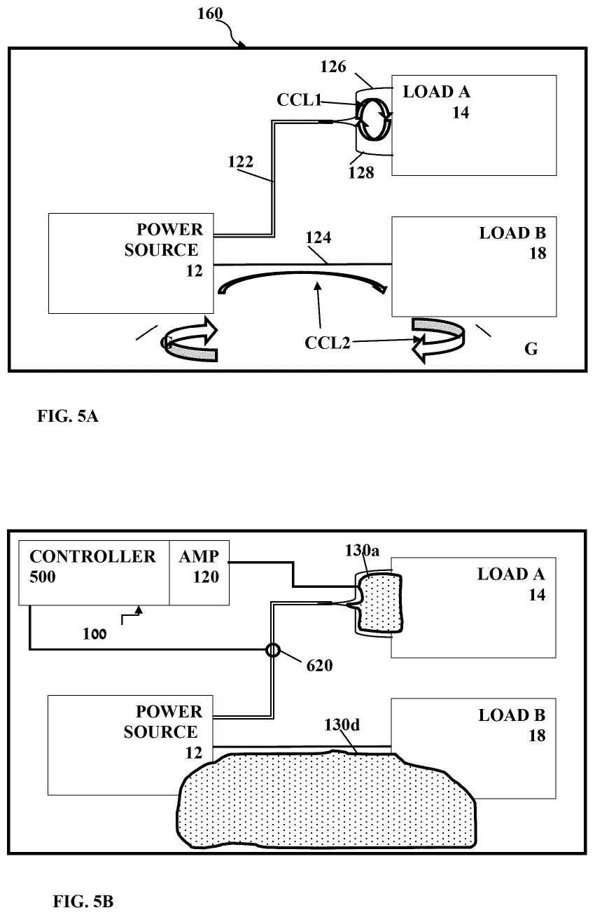

Further, reference is made to FIGS. 5A and 5B, schematically exemplifying a system 160, generally using electric power for operation of one or more load units 14 and 18. The electrical power is provided from a power source 12, e.g., battery pack/array or inventor providing one or more phases of a three-phase power supply, and transmitted to the load 14 via electrical transmission lines 122, 124, 126, 128 and/or ground connection G. FIG. 5B illustrates the system 160, with addition of magnetic field cancellation system 100 according to some embodiments pf the present disclosure.

As shown in FIG. 5A, electrical power is transmitted from power source 12 to the load units 14 and 18 using electrical transmission lines carrying electrical current. For example, electrical transmission line 122 is formed of a twisted cable pair carrying current to and from power source 12 to load unit 14. Generally, line 122 may represent a bundle of three-phase electric feed including phases P1, P2 and P3 as exemplified in FIG. 1. In various situations, resulting from mechanical or electrical constraints, the twisted cable 122 may split to first and second cables 126 and 128, e.g., exemplifying three-phase cables, first and second, plus and minus, contacts of the load unit 14. In this connection and in accordance with electrical signal scheme used by system 160, the first and second cables 126 and 128, may have various representations such as plus/minus, phase/zero, etc., or represent three-phase electric cables P1-P3 as described above. In general, irrespective of the specific electrical signal scheme, current that is transmitted to the load in one of the cables, is transmitted back to the power source 12 in the other cable.

It should be noted that power source 12 may be an AC or DC power source, and may often be a three-phase alternating current source. For example, in a typical electric or hybrid electric vehicle, the power source 12 includes one or more battery arrangements providing DC electrical power. However, in accordance with power consumption configurations, and/or following the use of rectifying circuits. The output electrical power may generally include AC components.

The current path formed by first and second cables 126 and 128, generates an effective current carrying loop (CCL), where the current transmitted to load A 14 circles in the loop CCL1. Current flow within the loop generates magnetic field in accordance with magnitude and variation frequency of the current.

Another example illustrated in FIG. 5A, includes a single power transmission line 124 extending between the power source 12 and load unit 18. In such configuration, the load unit 18 and power source 12 are further connected to a common ground connection G, thereby closing the electric circuit. The common ground may for example be frame or chassis of the system 160. As a result, the electrical current is transmitted through power line 124, and the common ground connection G, generating a current carrying loop CCL2.

In this connection it should be noted that current carrying loops CCL1 and CCL2 are illustrated together for simplicity, and to exemplify main types of current carrying loops that can be found in electrical systems. Further, it should be noted that the power source 12 is illustrated herein as a single power source, however, in a typical system different loads and accordingly different CCLs may be connected to one or more different power sources, providing selected and not specifically similar output voltage and current characteristics. Also, it should be understood that a CCL may be formed at any point along electrical conduction lines and may be associated with separated electric contacts at the power source 12, distance between electric contacts at the load 14, both or any other configuration where the electric lines are spatially separated generating a CCL.

Electrical currents flowing in a loop pattern enhance the magnetic fields generated by the moving charges. Generally, direct current (DC) generates static magnetic field, while alternating current (AC) portions cause variations in the magnetic field, associated with electromagnetic radiation having frequency that corresponds with the AC frequency of the currents. Thus, in some disclosed embodiments, the aggressor magnetic field may include an electromagnetic field. To eliminate, or at least significantly reduce magnetic fields and/or electromagnetic radiation in selected region in vicinity of the electrical system 160, the system and technique of the present disclosure utilize one or more parallel electrical wire loops, and generally first and second wire loops positioned to conform with three-phase cables as described above. The first and second parallel electrical wire loops are placed to overlap with cables of the three-phase electric feed, forming CCL1 identified in the electrical system 160. More specifically, the first and second parallel electrical wire loops may be placed to align with conductors of one or more CCLs to spatially conform with the respective CCLs. Current transmission in the parallel electrical wire loops is determined to be opposite in direction, and preferably as close in amplitude (current level), to current flowing in the respective CCL, to effectively cancel the magnetic fields generated by the current flowing in the CCL. This is illustrated in FIG. 5B, showing additional parallel electrical wire loops 130a placed to be generally overlapping with current carrying path of CCL1, wire loop 130d is illustrated overlapping with CCL2 to further reduce or cancel magnetic field generated therefrom. In other words, parallel electrical wire loops 130a including first and second wire loops is positioned to spatially conform to physical path of the respecting CCLs, such that the CCL and the respective parallel electrical wire loops act as a common source for magnetic field.

As illustrated in FIG. 5B, parallel electrical wire loops 130a and 130d are placed to overlap with path of electrical current defining current carrying loops CCL1 and CCL2. The parallel electrical wire loop 130a and 130d are connected to an electrical control system 100 including at least an amplifier 120, and sensor 620. System 100 may also include a controller 500 enabling processing and control for proper system operation. For simplicity of the illustration, system 100 is illustrated being connected to parallel electrical wire loop 130a only. It should however be understood that parallel electrical wire loop 130d may also be connected to system 100 or to a corresponding system, which may be the same or a separated control system. Further, it should be understood that each parallel electrical wire loop, and the respective control system 100 may be associated with respective one or more current sensors 620, placed for sensing current in selected current transmission lines feeding the corresponding CCL. Further, system 100 may utilize input data from power source 12 to determine cancellation current in addition or as an alternative to sensor 620.

The current sensor 620 may be positioned to provide sensing data indicative of electrical current transmitted in one or more current carrying lines that feed the respective current carrying loop. Generally, the current sensor 620 may be any type of current sensing unit capable of generation real-time output data about electrical current passing through a respective current carrying wire/line, such as current clamp sensor. In some configurations, current sensor 620 may be replaced by a field probe positioned for determining magnetic field at a selected location nearby a current carrying line. Preferably, to allow cancellation of high-frequency EMF, sensor 620 is generally a current sensor configured for generating sensing data indicative of current and current variations. The sensor may wide band sensor having a known frequency response function, such as flat phase response function. Alternatively, the controller 500 may be adapted for compensating for variation in frequency response function of the sensor 620, e.g., when the response function is not known. This may be used to provide phase accurate sensing data indicative of AC current variations and enable cancellation of EMF generated by varying electrical currents. In some configurations, the current sensor 620 may be configured with a phase shift, in one or more selected frequency ranges, being below a predetermined threshold. This configuration enables selection of current sensor based on frequency range of operation of electrical system 160, and range of frequencies in which EMF generated by the respective CCL is to be canceled. The current sensor 620 may be an electrical transducer suitable for measuring AC currents such as high-speed transients, pulsed currents of a power device, or power line sinusoidal currents in selected one or more frequency ranges. For example, the current sensor 620 may be a Rogowski coil current probe or other suitable current probes.

The sensor 620 is configured to provide current sensing data to an amplifier unit 120. The amplifier 120 is configured to receive the current sensing data and transmit corresponding electrical current to the parallel electrical wire loop 130a connected thereto. Electrical connections between amplifier 120, parallel electrical wire loop 130a, and sensor 620 are configured to provide the output current from amplifier 120 is opposite in direction to detected current passing the in respective CCL. Additionally, the amplitude of the current transmitted in parallel electrical wire loop 130a is substantially similar to amplitude of the current detected in the respective CCL. More specifically, given that the sensor 620 provides sensing data indicative of current I(t), the amplifier 120 is operated to provide output cancelling current being −kI(t) where k~1. Due to this configuration, parallel electrical wire loop 130a is operated to generate EMF that is equal in magnitude and opposite in direction to EMF generated by the respective CCL, and effectively cancels the CCL generated EMF. Accordingly, amplifier 120 may be selected in accordance with frequency response function thereof, to provide output signal having known phase relation with input sensing data on detected current. The phase relation may preferably be flat, allowing similar or opposite phase of the output signal. As indicated above, frequency range in which the frequency response function is of flat phase may be selected in accordance with frequency range of current variation in system 160, to thereby enable effective cancellation of EMF generated by the respective CCL. Generally, the amplifier 120 may be formed as a two-stage amplifier or more, including a variable gain amplifier stage and a power amplifier stage. Operation of the variable gain amplifier enables adjustment of amplification parameter k to provide k~1, i.e., minimize the function |k−1|.

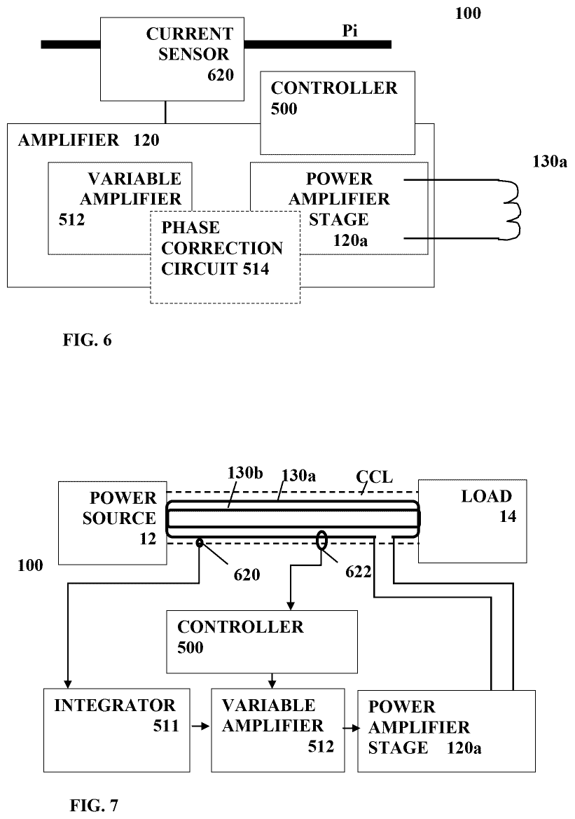

An exemplary configuration of magnetic field cancellation system 100 according to some embodiments of the present disclosure is illustrated in FIG. 6. As shown, the system includes a current sensor 620 positioned to detect current in one or more electrical lines Pi (e.g., P1-P3 as shown in FIG. 2) feeding a selected CCL, and an amplifier 120. The system 100 may also include a controller 500 providing processing and user interface for operation of the system. Amplifier 120 may be a two-stage amplifier including a first variable gain amplifier 512 having known phase shift for selected frequency range, and a power amplifier stage 516. In some configurations, in accordance with known phase shift of the variable gain amplifier 512, the amplifier unit 120 may also include a phase correction circuit 514 configured to align phase of amplified signal to phase of current detected by the sensor 620. The power amplifier stage 120a provides output current, that is generally similar in magnitude, and opposite in phase to current detected by sensor 620. The output current is directed to flow through parallel electric wire loop 130a (and 130b) position as described herein to substantially overlap a selected CCL in the system, to thereby cancel magnetic field generated by the CCL.

For example, the amplifier unit 120 may be selected in accordance with one or more requirements. An initial requirement is based on phase shift. Accordingly, the amplifier should enable operation with predetermined, and preferably zero phase shift. The amplifier 120 may be selected having one or more electrical requirements as indicated in table 1.

TABLE 1

| | |
|---|---|
| Input Frequency range | 10 Hz to 5 Khz |
| Input voltage | 1-100 m Vrms (DC up to 1 Volt) |
| Input impedance | >1 Kohm |
| Floating input (h and L) | <100 Vdc |
| to DC supply | |
| AC current output | max 5Apeak |
| Maximum output voltage | 12 V |
| Antenna resistance | 0-2 Ohm, 10 microHy to 500 microHy |
| Vout (DC) | below 100 mV |
| Floating outpur (h and L) | up to 50 Vdc |
| to DC supply | |

Generally, the amplifier may operate in amplification range with 1-50 m Vrms input voltage and 0.1-5 Arms output current, total harmonic distortions below 5% and to allow phase shift below 1 degree within the selected frequency range. The amplifier 120 may operate using single or dual power supply in the range of 10-26V (DC). The amplifier 120 may include an undervoltage protection and may be configured with 2 supply lines with internal sum.

Although, presence of static magnetic field is generally not desired, cancelling of such static magnetic fields are typically of less interest compared to varying magnetic fields, or EMF, typically due to possible health hazards known to be associated with varying EMF. To this end, scoring of CCLs may be determined in accordance with amplitude and frequency of current variations. Further, the sensing data, and amplifier may be configured for providing the parallel electric wire loop with current pattern that is directed at eliminating AC components of the CCL current, to eliminate, or at least significantly reduce EMF emitted by the CCL. In some configurations, the sensor 620 is configured to provide sensing data indicative of AC components of electric currents at frequency ranges between 10 Hz and 5 KHz. The amplifier 120 may thus be configured for operating in the selected frequency range, considering possible phase shifts in the selected frequency range.

Operation for canceling magnetic field generated by AC components of electric current also allows energy saving as it omits the need to transmit high DC current to counteract DC components of the CCL current. To this end, the amplifier 120 may be associated with a high-pass filter adapted for removing DC components from the sensing signal and transmit AC components of a selected frequency range, e.g., exceeding a selected threshold. This configuration is used for reducing EMF components over the slow-varying magnetic fields, thereby operating with reduced energy and reduced current transmission in the parallel electric wire loop. Further, as described in more details below, the power required for canceling magnetic field using the present technique relates to the current used multiplied by the load of the parallel electric wire loop 130a (and 130b as described above). Proper selection of the loop 130a parameters, such as resistance and inductance enable to minimize the operation power of the system.

Further, in some embodiments, the amplifier 120 may be associated with a band-pass filter adapted for filtering selected frequency components from the sensing signal. This enables transmission of AC components within a selected frequency band to cancel selected frequency band of magnetic fields. In some additional configurations, the amplifier 510 may be associated with a low-pass filter. This may be used for canceling the relatively strong, low frequency magnetic fields.

As indicated above, current cancelling system 100 according to the present disclosure may also include a controller 500. Controller 500 may generally include a processing utility, memory utility and user interface module, and is configured to provide controlling functions to system 100. Controller 500 may thus include a processor and memory circuitry (PMC) operatively connected to a hardware based I/O interface controlling operation of sensor 620 and amplifier 120. Controller 500 may be configured to provide processing necessary for operating the system 100 as further detailed herein and comprises a processor and a memory (as illustrated in FIG. 3). The processor of controller 500 can be configured to execute several functional modules in accordance with computer-readable instructions implemented on a non-transitory computer-readable memory comprised in the controller 500. Such functional modules are referred to hereinafter as comprised in the controller 500.

In some embodiments, sensing data, collected by current sensor 620 may be transmitted to controller 500 for processing and determining current pattern to be transmitted, by amplifier 120, through the parallel electrical wire loop 130a (and 130b as described above). Such processing may be used in configurations where the current that is provided to the load follows selected patterns and thus current parameters are predictable. In other configurations where the current patterns may vary without a distinct predictable pattern, analog operation may be preferred. In analog operation, the sensed current signals are amplified and transmitted in opposite phase through the parallel electrical wire loop 130a and 130b.

The electrical system 160, may generally be any system that utilizes electrical power for its operation. In some embodiments of the present disclosure, system 160 may be a vehicle, such as electric or hybrid electric vehicle. In such vehicles, passengers may spend long time periods within the vehicle, being generally exposed to high magnetic fields and EMF generated by the vehicle's electrical system. The present technique utilizes one or more current parallel electrical wire loop placed in selected locations to cancel, or at least significantly reduce electromagnetic fields applied on the passengers in the vehicle.

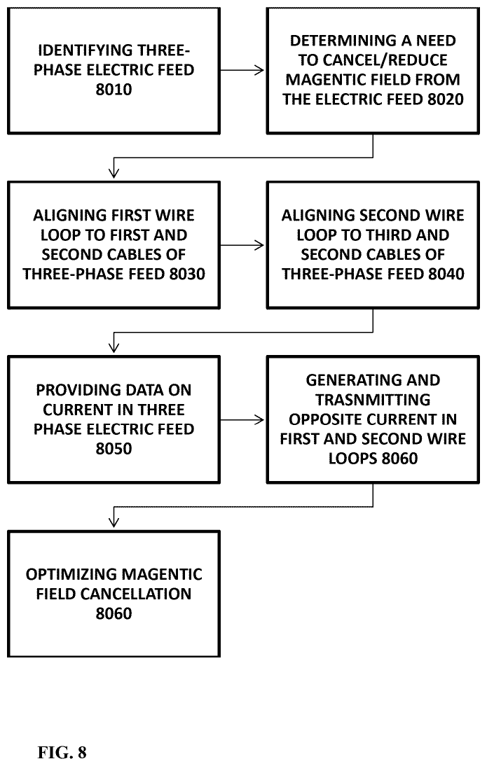

An additional example is illustrated in FIG. 7 showing system 100 for cancellation of magnetic field. The system 100 includes first and second electric wire loops 130a and 130b, illustrated as being placed to overlap with CCL (marked in dashed lines) extending between a power source 12 and load 14. The system 100 utilizes a current sensor 620 positioned to provide data on current feeding the CCL (the sensor may be placed along the CCL or along electric lines feeding the CCL as exemplified above). The current sensor provides current data to an integrator 511 configured to operate the variable gain amplifier 512 (or to provide current data directly to the amplifier 512). When output current is transmitted by the power amplifier stage 120a, the controller may operate to adjust the gain for optimized cancellation of the magnetic field. To this end, an additional current sensor 622 may be placed to measure the total current transmitted through the CCL and the parallel electric wire loops 130a and 130b, and to provide current data to the controller 500. Controller 500 is thus configured to adjust gain and phase levels to minimize the current detected by sensor 622 being combined CCL and loops 130a and 130b currents. Accordingly, sensor 622 is configured to provide difference sensing data indicative of difference in currents transmitted through the CCL and the respective loops 130a and 130b. This configuration provides a simple feedback system for accurately cancelling magnetic fields by providing opposite current to overlapping loops.

Further, reference is made to FIG. 8 illustrating a method for cancelling magnetic field of three-phase electric feed according to some embodiments of the present disclosure. As show, the technique is based in identifying a three-phase electric feed 8010. This may include identifying a need to cancel magnetic field generated by the feed lines 8020 as well as identifying the feed lines themselves and a region where the feed lines are separated and generate magnetic field.

To employ the magnetic field cancellation system, the method includes aligning a first wire loop to conform with path of first and second lines of the three-phase electric feed 8030. The first wire loop is aligned to conform with the first cable of the three-phase feed in one direction, and to conform with the second cable of the three-phase electric feed in the other direction. Similarly, the method includes aligning a second wire loops to conform with path of third and second cables of the three-phase electric feed 8040. Similarly, the second wire loop is aligned to conform with the third cable of the three-phase feed in one direction, and to conform with the second cable of the three-phase electric feed in the other direction.

Generally, as indicated above, the first and second wire loops may partially conform to cables of the three-phase feed, for example, in situations where access to the three-phase feed is limited, the first and second wire loops may be placed at a selected distance toward region where magnetic field is to be minimized. This provides reduction of the magnetic field, and may be used when access to the electric cables is limited.

During operation of the system, the method includes providing data on current transmitted in the three-phase feed 8050. The data may be determined using one or more sensors and/or using input data from the power source. Using the data on current transmitted in the three-phase electric feed, the present technique operates to generate and transmit an opposite current in the first and second wire loops 8060. As described above, the opposite currents operate to generate magnetic field in opposite direction and thus to cancel, or at least reduce, magnetic field generated by the three-phase electric feed. Further, as described above, both the first and second wire loops conform with one (e.g., second) of the three-phase electric cables such that sum of currents in the first and second wire loops is together opposite to current in the respective cable of the three-phase feed.

Typically, during operation, the technique of the present disclosure may also monitor magnetic field in a selected region where magnetic field is to be minimized, and operate to optimize magnetic field cancellation 8060. This may be done by phase and/or amplitude adjustments due to variation that may be associated with capacitance, and/or inductance of electric cables/wires in the system.

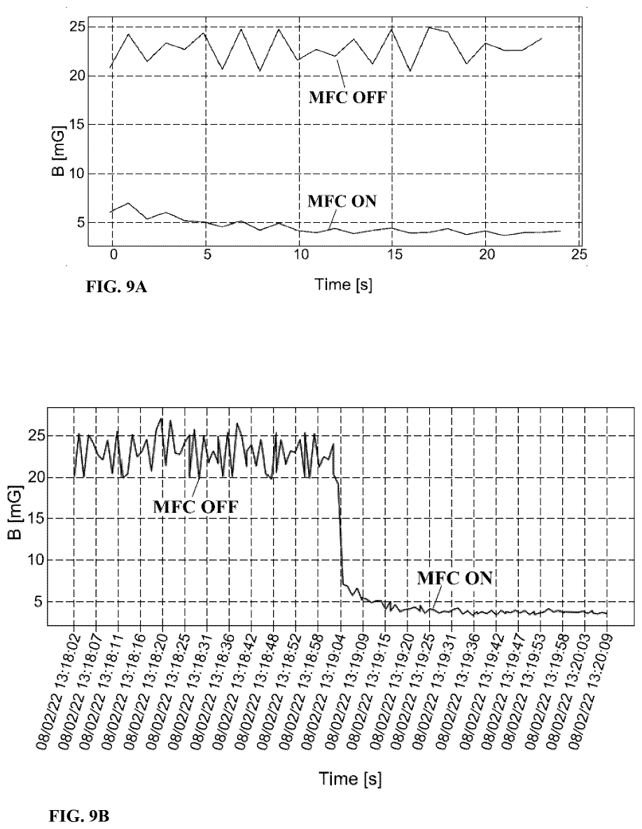

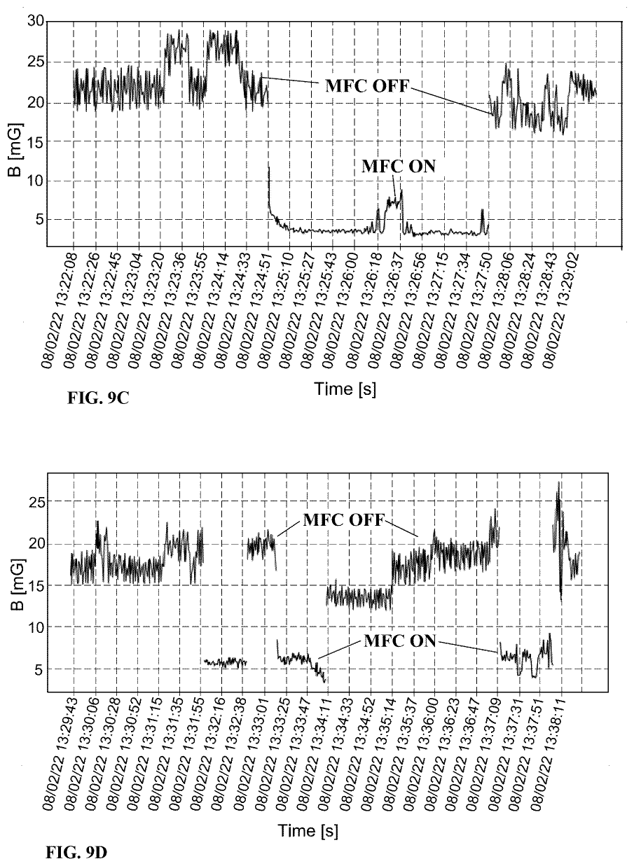

Cancelling magnetic fields using some aspects of the present technique was tested using a Hyundai Ioniq hybrid electric vehicle, commercially available. The vehicle includes two main electrical systems including a low voltage (e.g., 12V) electrical wiring including ground connection via the vehicle chassis, and a high voltage electrical wiring where the battery connections are separated generating a CCL between the positive and negative plugs. Magnetic field in the passenger compartment of the vehicle was measured using a magnetic field measurement unit, e.g., Tenmars TM-192\D triaxial magnetic field meter, during vehicle operation with the magnetic field cancellation system described above in idle and operation modes. FIGS. 9A to 9D show magnetic field measurements during different vehicle operation statuses. FIG. 9A shows comparison of magnetic field measurements when the vehicle is parked; FIG. 9B shows comparison on magnetic field measured during slow driving of the vehicle; FIG. 9C shows a comparison of magnetic field measured during urban driving within a city; and FIG. 9D shows magnetic field measured during intercity driving. To provide cancellation magnetic field, two parallel electric wire loops were placed in the vehicle. A first loop is placed to overlap a CCL formed by splitting of twisted wire pair transmitting electricity from a high voltage battery to a voltage converting arrangement within the vehicle. The first loop generally corresponds with parallel electrical wire loops 130a illustrated in FIG. 5B. A second loop extends to overlap with CCL connecting a low voltage battery unit with the voltage converting arrangement of the vehicle. The second loop corresponds with parallel electrical wire loops 130d illustrated in FIG. 5B. As described above, the second loop includes a path in which electrical current is transmitted through a portion of the vehicle chassis.

In more details, FIG. 9A shows magnetic fields measured in the rear seat of the vehicle when the vehicle is standing still, when the vehicle is turned on and in parking gear. As shown, when the magnetic field cancelation system MFC described above is turned off (MFC OFF) the magnetic field in the passenger seat is measured at 20-25 mG. The magnetic field measured with the system turned on (MFC ON) is found to be in the range of 2.5-7 mG, mostly in the range 2.5-3 mG. FIG. 9B shows similar results measured during slow driving, in which the vehicle is operated using the electric motor. The measured magnetic field was reduced by operation of the present technique from 20-25 mG to about 4 mG.

In FIGS. 9D and 9D, the magnetic fields were measured during driving in real lie environments. FIG. 9C shows measurements taken during urban driving showing that magnetic field was reduced from 20-25 mG, with peaks in the range of 25-30 mG to about 4 mG with peaks of 7-8 mG. FIG. 9D shows magnetic field values measured during intercity and highway driving. As shown, during relative high-speed driving, the magnetic field was measured at 15-23 mG with peaks of about 27 mG with the system turned off. When the system was turned on, it provides reduction in magnetic field to about 5-7 mG. This situation may be different in electric vehicles that rely only on electric motors, keeping in mind that some electric motors may operate with electric current of varying frequency, such that increase frequency is directed to rotate the motor at higher speed, leading to greater vehicle speed.

Generally, the magnetic field measurement device used provides measurements of magnetic field over time. The results show relate to magnitude of the magnetic field vector determined based on magnitude of the field measured in three orthogonal axes over time. The magnetic field measurement device operates with an impulse response providing a band-pass filter for a range between a few Hz o a few KHz. Accordingly, the measured magnetic fields relate to AC components (i.e., frequencies above 0 Hz).

Accordingly, the present disclosure provides a system and a technique suitable for eliminating, or at least significantly reducing magnetic fields generated by electrical currents in a system. The present technique is specifically adapted for operating in electric or hybrid electric vehicles, reducing magnetic and electromagnetic fields at the passenger seating regions of the vehicle. As indicated above, the present technique is based on inventor's understanding of arrangement of current carrying loops within the electrical system, and the role of such current carrying loops in generation of magnetic fields in vicinity of the system.

It should be noted that the example of FIGS. 9A-9D illustrates single phase cancellations, however, as discussed above, the use of first and second wire loops may provide magnetic field cancellation for three-phase electric feed, while not requiring a third loop as would possibly be expected.

Thus, the present disclosure provides a system and method for cancelling, or at least reducing magnetic field generated by a three-phase electric feed between a power source and a load. The present disclosure utilizes first, and second wire loops arranged to at least partially conform with cables of the three-phase electric feed, such that a first loop conforms with first and second cables of the feed, and second loop conforms with second and third cables of the feed. This configuration enables cancellation of magnetic field to a certain extent, while allowing the use of two wire loops and respective current source arrangement.

It is to be noted that the various features described in the various embodiments can be combined according to all possible technical combinations.

It is to be understood that the invention is not limited in its application to the details set forth in the description contained herein or illustrated in the drawings. The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based can readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

Examples of some inventive concepts are contained in the following clauses which are an integral part of this disclosure.

Clause 1. A system for reducing magnetic field generated by a three-phase electric wiring, the system comprising:
at least one current source unit configured to provide at least two output currents having selected current level and frequency;
a control unit adapted for receiving data on current passing through said three-phase electric wiring and for operating said at least one current source unit to generate cancellation current for reducing magnetic field generated by the three-phase electric wiring; and
an electric wire arrangement consisting of first and second electric wire loops, wherein the first wire loop is aligned to conform with electric cable of a first phase wiring in one direction and with electric cable of third phase wiring in a return direction, and wherein the second wire loop is aligned to conform with electric cable of a second phase wiring in one direction and with electric cable of the third phase wiring in a return direction.

Clause 2. The system of clause 1, comprising at least one sensor configured to provide sensing data indicating of current passing through said three-phase electric wiring.

Clause 3. The system of any of clauses 1 and 2, wherein said at least one sensor comprises a current sensor positioned for sensing data on current transmitted through at least one of said three-phase electric wiring.

Clause 4. The system of any of clauses 1 to 3, wherein the control unit is connectable to an external control for receiving input data indicative of current transmitted through said three-phase electric wiring.

Clause 5. The system of any of clauses 1 to 4, wherein said external control is a vehicle management computer.

Clause 6. The system of any of clauses 1 to 5, wherein said at least one current source unit is configured to transmit alternating current having phase shift of ±120 degrees between said first and second electric wire loops.

Clause 7. The system of any of clauses 1 to 6, wherein said at least one current source is configured to generate electric current having amplitude similar to current amplitude in said three-phase electric wiring.

Clause 8. The system of any of clauses 1 to 7, wherein said current amplitude is varied by a current gain factor for compensating on misalignment between said three-phase electric wiring and said first and second electric wire loops.

Clause 9. The system of any one of clauses 1 to 8, wherein said first and second electric wire loops being configured with two or more windings, confirming with respective path of electric cables of said three-phase electric wiring, thereby generating selected cancellation magnetic field utilizing reduced electrical current input.

Clause 10. A method for reducing magnetic fields generated by a three-phase electrical feed line, the method comprising: aligning two electrical wires to conform with two of the three-phase feed lines extending from a power source to a load, and aligning said two electrical wires in a reverse direction to conform with a third of the three-phase feed lines from the load to the power source; detecting data on current passed through the three-phase electrical feed line and transmitting an opposite current pattern through the two electrical wires, thereby cancelling magnetic field generated by said three-phase electrical feed line.

1. A system for reducing a magnetic field in a vehicle, the system comprising:
a passenger compartment in the vehicle;
a three-phase electrical wiring in proximity to the passenger compartment, wherein the three-phase electrical wiring includes a first cable, a second cable, and a third cable, that when in use, generate an aggressor magnetic field in the passenger compartment of the vehicle;
a first cancellation loop having a first leg and a second leg; and
a second cancellation loop having a third leg and a fourth leg,
wherein the first cancellation loop includes a first non-overlapping section along at least a portion of the first cable, wherein the second cancellation loop includes a second non-overlapping section along at least a portion of the third cable, and wherein the first cancellation loop and the second cancellation loop partially overlap along at least a portion of the second cable, to thereby facilitate cancellation of the aggressor magnetic field emanating from the three-phase electrical wiring.

2. The system of claim 1, wherein, when the system is configured such that when in use currents flow in opposing directions in the partially overlapping portion.

3. The system of claim 1, wherein each of the first cancellation loop and the second cancellation loop include multiple windings.

4. The system of claim 1, wherein, when in use, AC current flowing through the first, second, and third cables are phase shifted from each other by 120°.

5. The system of claim 1, wherein current flowing in the non-overlapping section of the first cancellation loop along the at least portion of the first cable substantially cancels current flowing in the at least portion of the first cable, wherein current flowing in the non-overlapping section of the second cancellation loop along the at least portion of the third cable substantially cancels current flowing in the at least portion of the third cable, and wherein a combined current flowing in the partial overlap of the first cancellation loop and the second cancellation loop substantially cancels current flowing in the second cable.

6. The system of claim 1, wherein the three-phase electrical wiring connects an inverter to a motor.

7. The system of claim 1, further comprising ferromagnetic shielding material between the three-phase loop and the passenger compartment for attenuating the aggressor magnetic field generated by the three-phase electrical wiring.

8. The system of claim 1, wherein the aggressor magnetic field is an electromagnetic field.

9. The system of claim 1, further comprising a control unit for receiving data on current passing through the three-phase electric wiring.

10. The system of claim 9, further comprising at least one current source unit connected to the first cancellation loop and the second cancellation loop, wherein the control unit is configured to operate the at least one current source unit to generate cancellation current for reducing an aggressor magnetic field generated by the three-phase electrical wiring.

11. The system of claim 10, wherein the at least one current source is configured to generate electric current having amplitude similar to current amplitude in the three-phase electrical wiring.

12. The system of claim 11, wherein the current amplitude is varied by a current gain factor for compensating on misalignment between the three-phase electric wiring and the first cancellation loop and the second cancellation loop.

13. The system of claim 9, further comprising at least one sensor configured to provide sensing data to the control unit indicative of current passing through the three-phase electric wiring.

14. The system of claim 13, wherein the at least one sensor includes at least one of a Rogowski coil or a current probe.

15. The system of claim 9, wherein the control unit is associated with a vehicle management computer.

16. The system of claim 13, further comprising at least one amplifier configured to receive the sensing data and output cancellation currents to the first cancellation loop and the second cancellation loop.

17. The system of claim 16, wherein the at least one amplifier is a two-stage amplifier including a variable gain amplifier stage and a power amplifier stage.

18. The system of claim 16, wherein the at least one amplifier is associated with a frequency response function for providing an output signal having a known phase relation with the sensing data.

19. The system of claim 9, wherein the control unit utilizes analog processing.

20. The system of claim 9, wherein the control unit includes at least one processor and a memory.
